(19) United States
(12) Patent Application Publication
(10) Pub. No.: US 2016/0216294 A1
(43) Pub. Date: Jul. 28, 2016

(54) Electrical Spring Probe with Stabilization

(71) Applicant: Kurt F. Kaashoek, Scottsdale, AZ (US)

(72) Inventor: Kurt F. Kaashoek, Scottsdale, AZ (US)

(21) Appl. No.: 15/008,227

(22) Filed: Jan. 27, 2016

Related U.S. Application Data
(60) Provisional application No. 62/108,428, filed on Jan. 27, 2015.
(60) Provisional application No. 62/171,461, filed on Jun. 5, 2015.

(51) Int. Cl. G01R 1/067

(52) U.S. Cl. CPC G01R 1/06722

(57) ABSTRACT

An improved spring probe for a connector assembly includes an elongated electrically conductive contact and an elongated helical compression spring disposed about and attached to the contact. The compression spring includes a stabilization section configured to stabilize the spring probe in a cavity of a test socket body during assembly of the test socket body. The spring stabilization section includes integrated opposed stabilization coils to vertically stabilize the spring probe in the cavity. An insulated spacer is disposed on the conductive contact and has an annular surface configured to contact a wall of the cavity to stabilize and isolate the contact within the cavity to provide a controlled impedance coaxial probe.

### RELATED APPLICATIONS

This application claims the benefit of U.S. Provisional Application No. 62/108,428, filed Jan. 27, 2015, entitled “Electrical Spring Probe with Retained Stabilization,” and U.S. Provisional Application No. 62/171,461, filed Jun. 5, 2015, entitled “Electrical Spring Probe with Integrated Spring Stabilization” which are incorporated in their entirety herein by this reference.

### BACKGROUND

The subject invention relates to spring probes for electrically accessing various parts of printed circuit boards, semiconductor devices and other electric and electronic components. More particularly, the invention relates to an improved electrical contact spring probe for use in a test socket. The probe includes a compression coil spring disposed about an elongated electrically conductive contact. An insulated spacer is disposed about the contact to stabilize and isolate the contact in a controlled impedance coaxial cavity of the test socket, and the spring is configured to vertically stabilize the spring probe in the cavity during assembly.

FIGS. 1 and 2 show a conventional spring probe. As shown in those figures, such probes generally include at least one movable plunger 2, a barrel 3 having an open end 4 for containing an enlarged diameter section or bearing 6 of the plunger 2, and a spring 5 for biasing the travel of the plunger in the barrel 3. The plunger bearing 6 slidably engages the inner surface of the barrel 3. To retain the bearing 6 in the barrel 3, a crimp 7 near the barrel open end can be used, or the barrel can be deep drawn with the open end reduced.

The plunger 2 is commonly biased outwardly a selected distance by the spring 5 and may be biased or depressed inwardly into the barrel 3, a selected distance, under force directed against the spring 5. Axial and side biasing of the plunger 2 against the barrel 3 prevents false opens or intermittent points of no contact between the plunger 2 and the barrel 3. The plunger 2 generally is solid and includes a head or tip for contacting electrical devices under test. Some internal spring configuration probes, such as that shown in FIGS. 1 and 2, include two plungers with each having a bearing fitted in an opposite open end of a barrel. The two plungers are biased by a spring fitted in the barrel between the bearings of each plunger.

The barrel, and plunger(s) form an electrical interconnect between the electrical device under test and test equipment and as such, are manufactured from an electrically conductive material. Typically the probes are fitted in cavities formed through the thickness of a test socket. Assembly of the test socket includes placing a plurality of contact probes into precision machined cavities in plastic subassemblies. Generally, a contact side of the electrical device to be tested, such as an integrated circuit, is brought into pressure contact with the tips of the plungers protruding through one side of the test socket for maintaining spring pressure against the electrical device. Pads on a printed circuit board (PCB) connected to the test equipment are brought into contact with the tips of the plungers protruding through the other side of the test socket. The test equipment transmits test signals to the PCB, through the electrical contacts and to the device under test (DUT). After the DUT has been tested, the pressure exerted by the spring probes is released and the device is removed from contact with the tips of the probes. In conventional test systems, the pressure is released by moving the electrical device and probes away from one another, thereby allowing the plungers to be displaced outwardly away from the barrel under the force of the spring, until the enlarged-diameter bearing of the plunger engages the crimp on the barrel.

The process of making a conventional spring probe involves separately producing the compression spring, the barrel and the plunger. The compression spring is wound and heat treated to produce a spring of a precise size and of a controlled spring force. The plunger is typically turned on a lathe and heat-treated. The barrels are typically deep drawn and heat-treated. All components may be subjected to a plating process to enhance conductivity. The spring probe components are assembled either manually or by an automated process. The assembled spring probes are placed in cavities in a test socket body with potentially thousands of probes per test socket.

It is desirable to provide a probe that can be easily and inexpensively manufactured and assembled. As can be seen from the foregoing, the assembly of the probes and sockets is a multiple step process. The fabrication of the sub-assemblies requires costly custom machining or complex tooling. Considering that probes and sockets are produced by the thousands, a reduction in the equipment, materials and steps required to produce them can result in substantial savings.

An important aspect of testing integrated circuits is that they are tested under high frequencies. As such, impedance matching is required between the test equipment and integrated circuit so as to avoid attenuation of the high frequency signals. Leading edge test sockets can contain thousands of spring probes placed with minimal spacing (0.8 mm to 0.4 mm typical) making impedance matching impossible using traditional machined plastic socket bodies. For controlled impedance applications, test socket designs use conductive (i.e., metal) substrates isolating each signal contact probe in a coaxial cavity with an air gap dielectric where the diameter of the cavity is typically 2.5 times greater than the diameter of the signal contact probe. For these applications, it is desirable to stabilize the spring probe within the coaxial cavity when the test socket is in use. The metal substrate can be anodized to insulate the surface or the test socket may include additional insulated layers to isolate the conductive substrate from adjacent test system components.

A spring's operating life, as well as the force applied by a spring, is proportional to the wire length, the diameter of the wire forming the spring, and the diameter of the spring itself (i.e., spring volume). These requirements for a given spring operating life and force are in contrast with the spring requirements for controlled impedance coaxial contact probes running high frequency signals. In internal spring probes, the diameter of the spring is limited by the internal diameter of the probe barrel. High performance coaxial test sockets require ever closer cavity spacing and external contact probe diameters that are a fraction of the cavity diameter. Additionally, typical IC package leads contain lead free solder alloys that have hard oxide layers requiring high force to break though the oxides. Since the diameter of the spring is limited by the diameter of the barrel, which is limited by the gap required of high performance coax cavities, the only way to increase the spring volume for increasing the spring operating life, is to increase the overall barrel length or reduce the operating force. Doing so, however, results in a probe that has either low force incapable of breaking through lead free solder oxides or is too long, resulting in unacceptable electrical performance.

It is desirable to maximize spring volume and compliance without increasing spring length or reducing force. Probe spring compliance is defined by the distance of spring extension from its fully compressed position to its fully extended position in the probe. Typically, for a given application, a given spring compliance is required. With conventional probes, the volume of the spring is limited by the required compliance. A longer spring incorporated in a conventional internal or external spring probe will reduce the plunger stroke length and thus, reduce the distance that the spring can extend from a fully compressed position. For a given probe, as the spring compliance increases, the spring volume decreases and so does the spring operating life.

It also is desirable to stabilize a spring probe within a coaxial cavity during assembly of the test socket. An important aspect of test socket cost and quality involves the ease of loading spring probes into the test socket body for assembly and repair. Test sockets include top and bottom retainer plates with a plurality of holes matching the lead pattern and pitch of the device being tested. Test probes are loaded into the top retainer plate, upside down. The bottom retainer plate is placed, and secured on the top retainer plate after all spring probes are loaded in the test socket cavities. It is necessary for all of spring probes to be aligned vertically in the cavities in order to assemble the bottom retainer on the test socket without damaging spring probes. In the case of high performance coaxial cavity test sockets the loading is particularly critical given the large disparity between the spring probe diameter and the cavity diameter in an air dielectric coaxial cavity. Standard spring probes can lean in the coaxial cavities preventing the bottom retainer from being assembled on the socket or damaging spring probes during assembly of the bottom retainer plate on the socket.

Accordingly, it is an object of the subject invention to provide a new and improved test probe that is small enough to accommodate the increased density of leads on modern integrated circuit (IC) chips.

A further object of the subject invention is to provide a test probe that has durable and flexible contacts for connecting a component to a printed circuit board (PCB).

A further object of the subject invention is to provide a reliable test probe that will continue to operate as designed after numerous operational cycles.

Yet another object of the subject invention is to provide a test probe that is capable of use with leading edge IC packages, wafer level interconnects and others.

A further object of the subject invention is to provide a new and improved test probe that is inexpensive to manufacture and has a minimum number of parts.

A further object of the subject invention is to provide a test probe that does not damage the pads of the printed circuit board onto which it is mounted.

Another object of the subject invention is to provide a test probe that is suitable for use in high frequency impedance matching test applications.

Another object of the subject invention is to provide a test probe that can be used for high performance coaxial cavities of test sockets.

Yet another object of the invention is to provide a test probe configuration that stabilizes the probe vertically in the test socket cavity during socket assembly without affecting electrical performance.

A further object of the subject invention is to provide a spring probe that is operative to establish a maximum current carrying capability, minimum resistance, minimum inductance electrical connection between the lead of an integrated circuit and a printed circuit board.

Additional objects and advantages of the invention will be set forth in the description that follows, and in part will be apparent from the description, or may be learned by practice of the invention. The objects and advantages of the invention may be realized and obtained by means of the instrumentalities and combinations pointed out in the appended claims.

### SUMMARY

To achieve the foregoing objects, and in accordance with the purposes of the invention as embodied and broadly described in this document, there is provided an improved electrical spring probe for a connector assembly. The probe includes a first elongated electrically conductive contact having a beam and a head for contacting an integrated circuit package and a second elongated electrically conductive contact having a beam and a tip for contacting an electrical conductor. A compression spring has opposing first and second spring ends and a middle section intermediate the first and second spring ends. The compression spring has a first coiled section adjacent the first spring end and a second coiled section adjacent the second spring end. The first coiled section is disposed about and in contact with the first contact beam, and the second coiled section is disposed about and in contact with the second contact beam. The spring also has a stabilization section configured to stabilize the spring probe in the cavity during assembly of a test socket body. An insulated spacer is disposed on the first conductive contact and has an annular surface configured to contact a wall of a cavity in the test socket body when the spring probe is positioned within the cavity. The spring second coiled section includes one of more coils having a smaller diameter than that of the spring middle section.

In some embodiments, the insulated spacer is disposed on the first conductive contact intermediate the head and first spring end. The spring first coiled section is fixed to the first conductive contact and the insulated spacer is held in place on the first conductive contact by the spring first coiled section and the contact head. The first conductive contact can include a shoulder intermediate the head and the beam, and the first spring end can tightly hold the contact shoulder, wherein the shoulder restricts movement of the insulated spacer toward the contact head. The first conductive contact beam can include an annular groove and the first coiled section can include one or more coils that fit in the annular groove. The spring probe can include a second insulated spacer disposed on the second conductive contact, wherein the second insulated spacer has an annular surface configured to contact the cavity wall when the spring probe is positioned within the cavity.

In some embodiments, the spring stabilization section includes at least one stabilization coil having an outer diameter larger than the outer diameter of the spring middle section and larger than the diameter of the first coiled section and larger than the diameter of the second coiled section. The stabilization coil is configured to fit within the cavity when the spring probe is positioned within the cavity. The stabilization coil has an outer diameter that is less than the cavity diameter. In some embodiments, the stabilization coil is disposed on an axis generally parallel to and offset from a spring main axis.

In some embodiments, each of the first spring end and the second spring end includes a plurality of contiguous coils. The contiguous coils at the second spring end include one or more coils with a smaller coil diameter than the coil diameter of a section of the spring intermediate the first and second ends of the spring.

In some embodiments of the invention, the first coiled section is fixed to the first conductive contact, and the insulated spacer is held in place on the first conductive contact by the first coiled section and the head. The first coiled section includes one or more coils having a coil diameter that is smaller than the coil diameter of an intermediate coiled section of the spring between the first coiled section and the second coiled section. The second coiled section includes one or more coils having a smaller coil diameter than the coil diameter of an intermediate coiled section of the spring between the first coiled section and the second coiled section.

An electrical spring probe according to the invention can have impedance matching and stability within a coaxial cavity gap without sacrificing the probe spring operational life and compliance. Moreover, the probe can be easily manufactured and assembled with inexpensive components. In addition, the probe diameter is small enough to be used in the densities required by state of the art integrated circuit packages. Also, the probe has maximum current carry capacity and minimum electrical resistance and inductance.

### BRIEF DESCRIPTION OF THE DRAWINGS

The accompanying drawings, which are incorporated in and constitute a part of the specification, illustrate the presently preferred embodiments of the invention and, together with the general description given above and the detailed description of the preferred methods and embodiments given below, serve to explain the principles of the invention.

FIG. 1 is an elevation view of a traditional spring probe commonly found in the art.

FIG. 2 is an elevation view, in partial cross-section, of the traditional spring probe shown in FIG. 1.

FIG. 3 is an elevation view of one embodiment of a spring probe according to the present invention, showing the offset coil spring pressed between an upper contact and a lower contact and disposed around the upper contact beam.

FIG. 4 is a perspective view of one embodiment of a spring probe according to the present invention, showing insulated spacers retained on the upper and lower contacts and showing the offset coils of the spring.

FIG. 5 is an elevation view of the spring probe of FIG. 4 with insulated spacers.

FIG. 5A is an enlarged partial cut away view showing the upper insulated spacer of FIG. 4 on the contact shoulder, with the top coil of the spring positioned and held within in an annular groove in the upper contact shoulder.

FIG. 6 is an elevation view of the spring probe of FIG. 4, showing the spring probe disposed within a coaxial cavity in an uncompressed condition.

FIG. 6A is an elevation view of the spring probe and coaxial cavity of FIG. 6 showing the spring probe fully compressed between a PCB pad and solder ball lead of an IC package.

FIG. 7 is an elevation view of another embodiment of a coaxial spring probe in accordance with the present invention, which includes an upper insulated spacer and integrated stabilization coils.

FIG. 8 is an enlarged view of a portion of the spring probe of FIG. 7.

FIG. 9 is an elevation view of the spring probe of FIG. 7, showing the spring probe disposed within a coaxial cavity in an uncompressed condition and showing the stabilization coils positioned within the coaxial cavity of a top retainer plate.

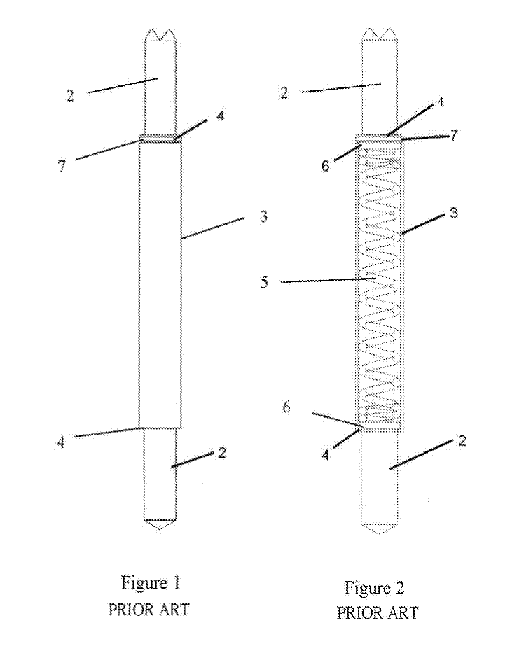

### DESCRIPTION

Reference will now be made in more detail to presently preferred embodiments of the invention, as illustrated in the accompanying drawings. While I will describe the invention more fully with reference to these examples and drawings, the invention in its broader aspects is not limited to the specific details, representative devices, and illustrative examples shown and described. Rather, the description which follows is to be understood as a broad, teaching disclosure directed to persons of ordinary skill in the appropriate arts, and not as limiting upon my invention.

It will be appreciated that terms such as “forward,” “rearward,” “upper,” “inner,” “outer,” “vertical,” “horizontal,” “bottom,” “below,” “top,” “side,” “inwardly,” “outwardly,” “downwardly” and “lower” and other positionally descriptive terms used in this specification are used merely for ease of description and refer to the orientation of the referenced components as shown in the figures. It should be understood that any orientation of the components described herein is within the scope of the present invention. The term “generally” as used in this specification is defined as “being in general but not necessarily exactly or wholly that which is specified.” For example, “generally cylindrically shaped” is used herein to indicate components that are in general, but not necessarily exactly or wholly, cylindrically shaped.

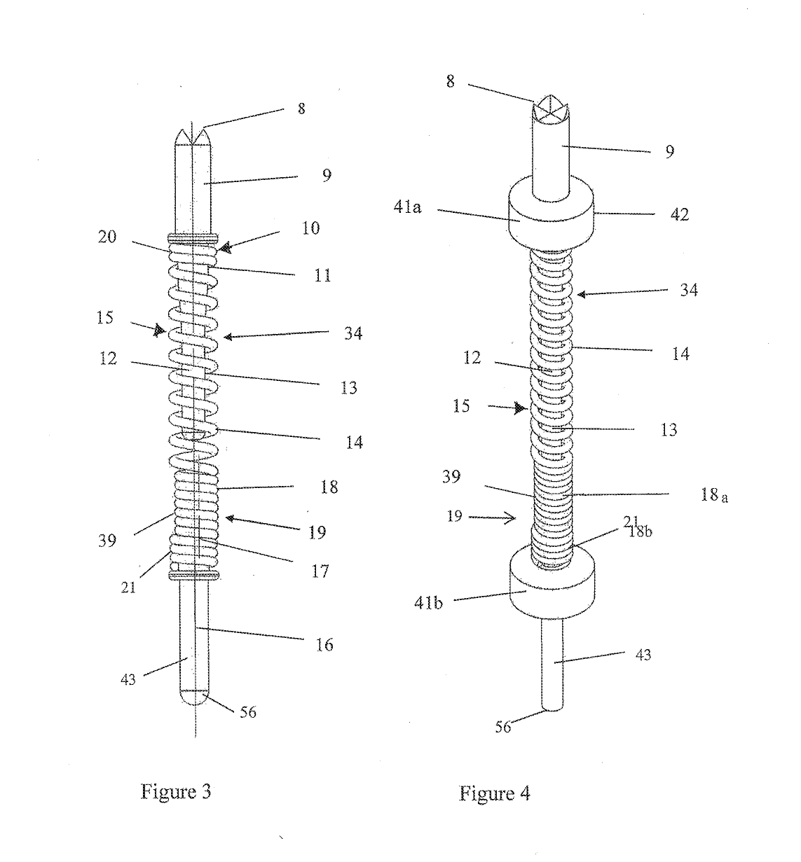

Referring to FIG. 3, an electrical spring probe 34, according to one embodiment of the present invention, includes an elongated upper contact 13 and a helical compression spring 14. In a preferred embodiment, the upper contact 13 is in the form of a machined pin. The upper contact 13 includes a head 9 with a crown tip 8 for contacting an IC package lead, such as a solder ball. It will be understood, however, that contact head 9 may have other tip configurations suitable for contacting other types of leads. For example, the head may have a rounded tip for contacting leads on flat-leaded IC packages such as LGA, MLF, QFN, and strip packages, and the like. The upper contact 13 also has a beam 12 opposite the head 9 and a shoulder 11 intermediate the head 9 and the beam 12. The shoulder 11 has a diameter that is smaller than the diameter of the head 9 and larger than the diameter of the beam 12. In the embodiment shown in FIG. 3, the upper contact 13 is fabricated in the form of a cylindrical CNC machined pin, but it will be understood that it can have other shapes (e.g., flat) and be fabricated by any suitable fabrication technique, including metal injection molding, stamping, roll forming, cold heading, etc.

Still referring to FIG. 3, the compression spring 14 is disposed about the upper contact 13. The compression spring 14 is generally cylindrically shaped and is formed from material having good spring characteristics, which permits resilient compression of the spring 14. Preferably, the compression spring 14 is formed from a single unitary conductor, which is coiled in a helical fashion. The spring 14 has an upper end 10, a middle section 15, and a lower end 19. The spring upper end 10 is attached to the upper contact shoulder 11. The spring upper end 10 has a section of coils 20 that are tightly wound such that they are contiguous. The inner diameter of the coils of the spring upper end 10 is slightly smaller than the diameter of the contact shoulder 11 to provide a tight fit between the spring upper end 10 and the contact shoulder 11. In this configuration, the compression spring 14 can be attached to the upper contact 13 by pressing the contact shoulder 11 into the spring upper end 10. The spring upper end 10, the contact beam 9 and the spring middle section 15 are disposed generally along a main axis 16. The spring middle section 15 is of open pitch configuration so that it can be longitudinally compressed under the action of opposing forces.

The spring lower end 19 is attached to an elongated lower contact 43 with a tip 56 that has a pointed, rounded or other geometry suitable for engaging a PCB pad. The spring lower end 19 includes a section of offset coils 18 and a section of non-offset coils 21, both of which are tightly wound such that each of the coils is contiguous with its adjacent coil. The diameter of the offset coils 18 of the spring lower end 19 is less than that of the coils of spring middle section 15. The inner coil diameter of the spring lower end 19 is greater than the diameter of the contact beam 12 to allow the contact beam 12 to enter into the spring lower end 19 when the spring probe 34 is compressed. The inner coil diameter of the spring lower end 19 is small enough, however, so that as the electrical spring probe is compressed, the contact beam 12 is deflected to bias it into firm contact with the spring lower end 19, as described below.

The spring lower end offset coils 18 are disposed generally along an axis 17 that is offset from the main axis 16. The offset coils 18 have a diameter that is smaller than that of the non-offset coils of the spring middle section 15, and the offset coils 18 are indented inwardly from one side of the adjacent non-offset coils of the spring middle section 15, thereby forming an indentation 39 along one side of a portion of the spring lower end 19. In this configuration, in operation, when the electrical spring probe 34 is compressed, the offset coils 18 of the spring lower end 19 deflect the contact beam 12 and bias it into firm contact with the offset coils 18 of the spring lower end 19 and establish a direct electrical path between the contact head 9 and the spring lower end 19.

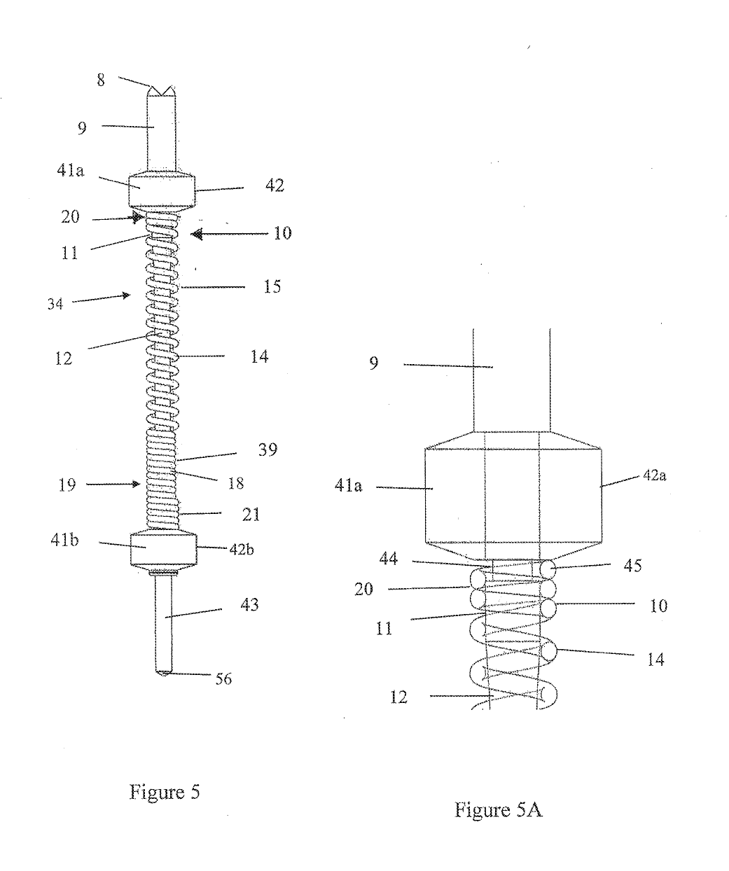

Referring to FIGS. 4 and 5-5A, one embodiment of an electrical spring probe 34 according to the present invention includes insulated spacers 41. An upper insulated spacer 41a is disposed about the perimeter of the upper contact 13 in a position intermediate the contact head 9 and the spring 14. The tightly wound contiguous coils 20 of the spring top section 10 hold the upper insulated spacer 41a securely on the upper contact 13. The outer diameter of the upper insulated spacer 41a is larger than the diameter of the contact head 9 and larger than the outer diameter of the compression spring 14. A lower insulated spacer 41b is disposed about the perimeter of the lower contact 43 in a position intermediate the spring lower end 19 and the lower contact tip 56. The outer diameter of the lower insulated spacer 41b is larger than the diameter of the lower contact 43 and larger than the outer diameter of the compression spring 14. The insulated spacers 41 can be ring shaped and formed of an insulated material such as polytetrafluoroethylene (PTFE) or other nonconductive material such as plastic, polymer, rubber, etc. Each of the insulated spacers 41 includes a cylindrical face 42 that stabilizes the contact 13 vertically and acts as a bearing surface within a coaxial cavity, as described below.

As shown in FIG. 5A, in one preferred embodiment, the upper contact shoulder 11 includes an annular groove or slot 44 disposed about the perimeter of the shoulder 11 below the head 9 and immediately adjacent the insulated spacer 41a. To hold the upper contact 13 firmly within the spring upper end 10, the contiguous coils 20 of the spring upper end 10 have an inner diameter that is smaller than the outside diameter of the upper contact shoulder 11. Moreover, an end coil 45 is smaller than the adjacent contiguous coils 20 and when pressed in place engages the annular groove 44, thereby accurately and securely positioning the spring upper end 10 on the upper contact shoulder 11 and preventing the spring upper end 10 from driving into the insulated spacer 41a under compression. The annular groove 44 shown is a rectangular channel but the groove can be any shape that securely retains the spring upper end 10.

Referring to FIG. 5, the lower contact 43 includes a shoulder (not shown) with a diameter slightly larger than the inside diameter of the non-offset coils 21 of the spring lower end 19 and a flange 51 with a diameter larger than the shoulder diameter and larger than the lower portion of the lower contact 43. The lower insulated spacer 41b is disposed around the shoulder of the lower contact 43 between the flange 51 and the smaller diameter non-offset coils 21 of the spring lower end 19, securely holding it in place.

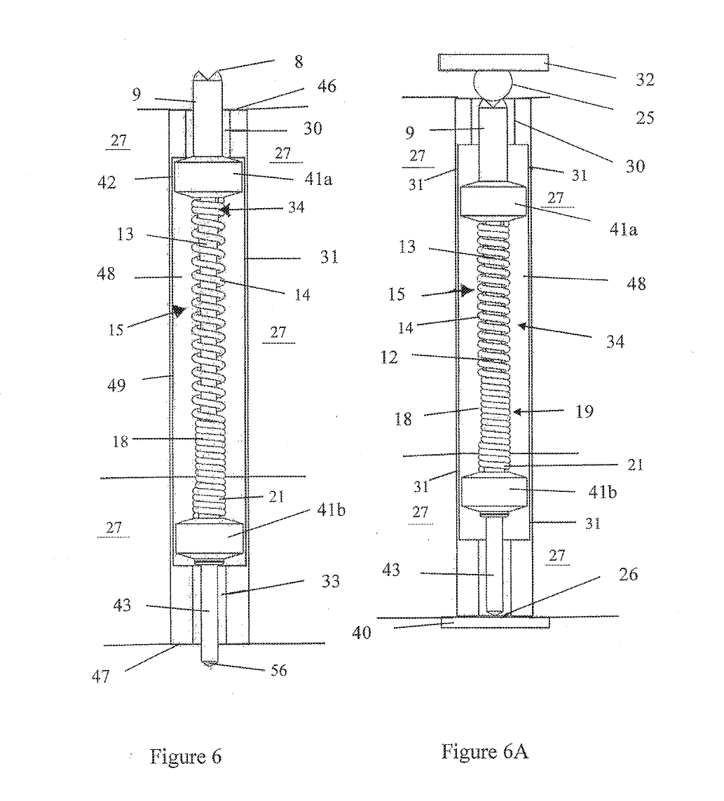

Referring to FIG. 6, the electrical spring probe 34 is shown positioned in a through-hole 31 of a coaxial test socket substrate 27. In one embodiment of such a test socket, the substrate 27 has a plurality of annular through-holes 31 extending between a top surface 46 and bottom surface 47 of the substrate 27. The through-hole 31 has an upper opening 30 and a lower opening 33, each of which has a diameter that is smaller than an enlarged diameter center portion 49 intermediate the upper opening 30 and lower opening 33. The through-hole 31 defines an air dielectric gap 48. In this configuration, each through-hole 31 holds an electrical spring probe 34 with the insulated spacers 41a, 41b positioned between the upper 30 and lower 33 openings of the through-hole 31. In FIG. 6, the spring probe 34 is shown in an uncompressed, initial rest position. The outer diameter of the spring probe 34 and inner diameter of the through-hole center portion 49 are set such that a coaxial structure of predetermined impedance is formed, where each spring probe 34 serves as a core conductor and the conductive substrate 27 serves as an outer conductor. The conductive substrate 27 can be aluminum or another conductive material. The conductive substrate 27 upper surface 46, lower surface 47, and through-hole 31 can be insulated by anodizing or adding an insulted film such as polyimide or other insulated material to prevent shorting with the electrical spring probe 34, IC package or PCB.

Still referring to FIG. 6, the upper contact head 9 has a smaller diameter than that of the upper opening 30 to allow the contact head 9 to move within the substrate upper opening 30 when the spring probe 34 is compressed. The diameter of the elongated lower contact 43 is smaller than the lower opening 33, thereby allowing the lower contact 33 to move within the lower opening 33 when the spring probe 34 is compressed. The outer diameter of the insulated spacers 41a, 41b is less than the inner diameter of the through-hole center portion 49 and is greater than the inner diameter of each of the through-hole upper opening 30 and lower opening 33, thereby retaining the spring probe 34 within the conductive substrate 27. The upper contact head 9 projects above the conductive substrate top surface 46, thereby enabling the upper contact head 9 to make electrical contact with an IC package lead. The lower contact 43 projects below the substrate bottom surface 47, thereby enabling the lower contact 43 to extend beyond the substrate bottom surface 47 to make electrical contact with a PCB pad.

Referring to FIG. 6A, the spring probe 34 is shown fully compressed between an IC package 32 and a PCB 40. The PCB 40 has a plurality of conductive pads 26 that must be electrically connected to the IC package leads 25 to test the IC. The number of the spring probes 34 will generally correspond to the number of leads 25, e.g. solder ball leads, provided with the IC package 32. Also, the size of the substrate 27 is generally dependent on the size of the IC package 32. It should be noted that the substrate 27 need not have the same dimensions as the IC package 32. However, the electrical spring probes 34 must be disposed within the substrate 27 such that the pressing contact is achieved between the upper contact heads 9 and the leads 25 of the IC package 32, with the spring probe 34 being placed in face-to-face contact with the IC package 32. The leads 25 may be disposed to define a plurality of rows and columns across the surface of the IC package 32. Consequently, although not shown, it will be understood that the electrical spring probes 34 are to be aligned in a similar row-column pattern.

Still referring to FIG. 6A, during a testing operation, the PCB pad 26 is brought into contact with the lower contact 43 so as to make electrical contact and to partially compress the compression spring 14. Next, the IC package 32 is pressed into the connector assembly and the lead 25 engages the upper contact head 9, thereby resulting in downward movement of the upper contact 13. In FIG. 6A, the spring probe 34 is shown being actuated downwardly within the substrate 27 by pressure from the IC package 32 on the upper contact head 9 so as to cause an electrical connection between the spring 14 and the PCB pad 26. In this position, the spring middle section 15 is compressed to accommodate the retraction of the spring lower end 19 upwardly within the through-hole 31.

As illustrated in FIG. 6A, as the spring 14 is further compressed, the upper contact 13 is moved downwardly into the through-hole 31, and the upper contact beam 12 bears against the offset coils 18 of the spring lower end 19. The contact beam 12 makes electrical contact with the offset coils, thereby providing a direct electrical path from the lead 25, through the length of the upper contact 13, through the offset coils 18, through the lower contact 43, and to the PCB pad 26. In effect, the contiguous offset coils 18 of the spring lower end 19 are equivalent to a solid cylindrical contact. As a result, the electrical path between the IC package lead 25 and the PCB pad 26 is a direct, almost straightforward path, which minimizes resistance and increases current carrying capability. The insulated spacers 41 stabilize the spring probe 34 within the air gap 48 of the coaxial cavity, thereby controlling the impedance and enabling the contact to operate at higher frequencies.

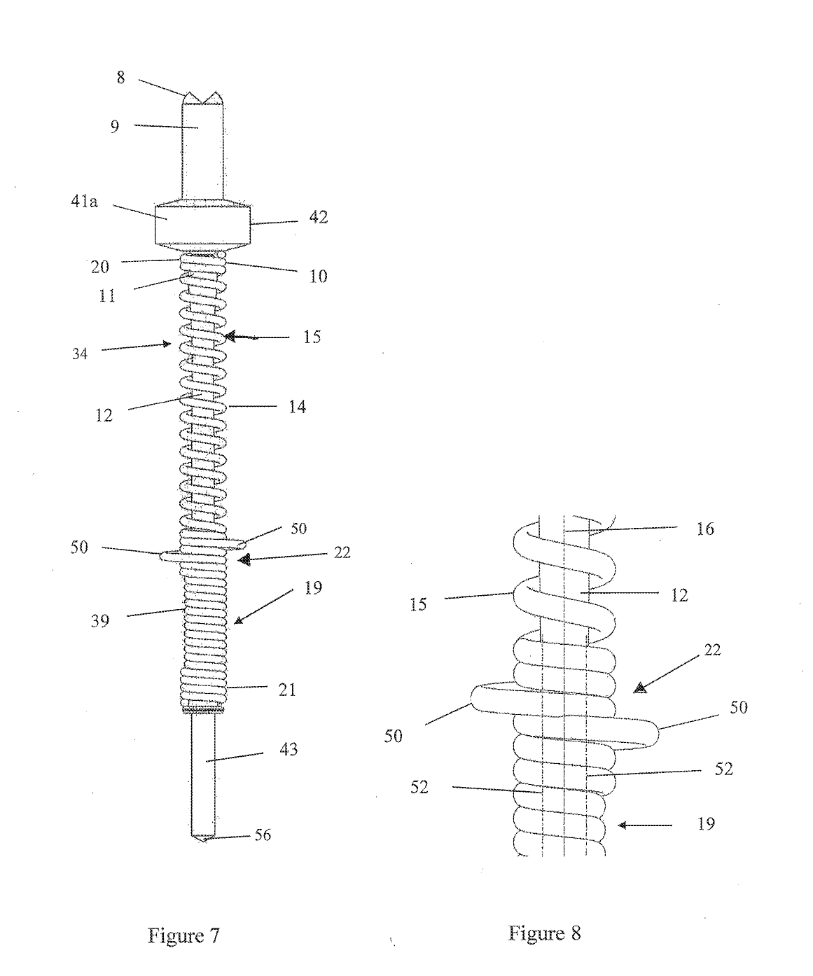

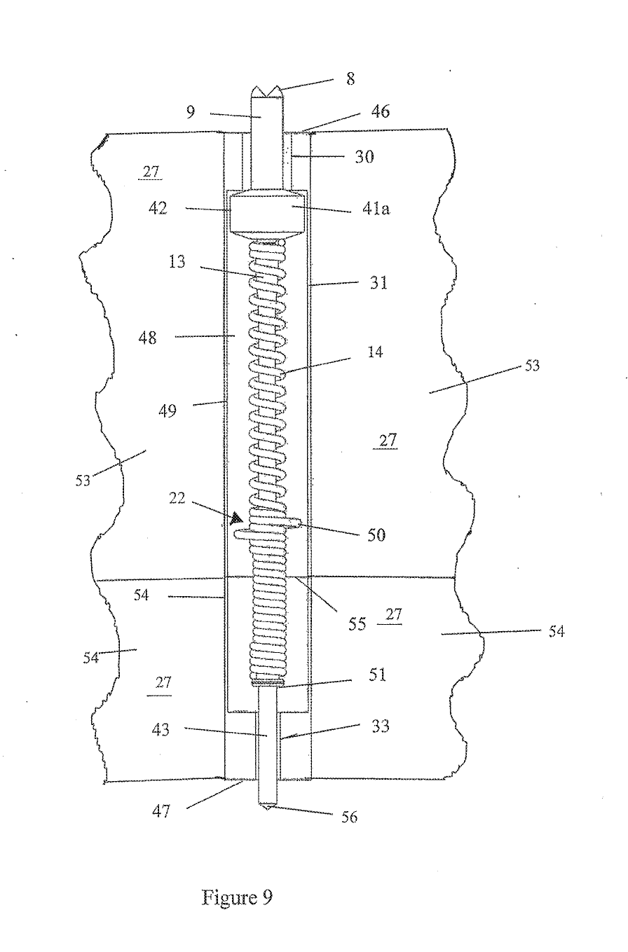

Referring to FIGS. 7 and 8, another embodiment of an electrical spring probe 34 according to the present invention includes the upper insulated spacer 41a, the elongated upper contact 13, the helical compression spring 14 and an elongated lower contact 43. The spacer 41a is disposed about the perimeter of the upper contact shoulder 11 in a position intermediate the head 9 and the compression spring 14, as previously described. The compression spring 14 includes a stabilization section 22 intermediate the spring middle section 15 and spring lower end 19. The stabilization section 22 includes two integrated larger diameter, vertically opposed stabilization coils 50, each of which has an outside diameter that is larger than the outside diameter of the spring middle section 15. The stabilization coils 50 are disposed axes 52 that are generally parallel to and offset from the spring main axis 16. The diameter of each stabilization coil 50 is smaller than the diameter of the coaxial cavity formed by the through-hole 31 in the test socket substrate 27 (see FIG. 9). The perimeter of the stabilization coil 50 is sized to stabilize the electrical spring probe 34 vertically within the through-hole 31.

Referring to FIG. 9 the electrical spring probe 34 is shown positioned in a through-hole 31 of a test socket. In one embodiment of such a test socket, the conductive substrate 27 has a plurality of through-holes 31 extending between the top surface 46 and bottom surface 47 of the substrate 27. The substrate 27 includes a bottom retainer plate 54 and a top retainer plate 53 with openings 55 to allow the spring probes to be loaded into a plurality of through-holes 31. When the top and bottom retainer plates 53, 54 are assembled, each through-hole 31 has an upper opening 30 and a lower opening 33, each of which has a diameter that is smaller than the enlarged diameter center portion 49 intermediate the upper 30 and lower 33 openings. The through-hole 31 includes an air gap 48 that acts as a dielectric. In this configuration, each through-hole 31 holds an electrical spring probe 34 by way of an upper insulated spacer 41a and a flange 51 of the lower contact 43, positioned between the upper and lower openings 30, 33 of the through-hole 31. The compression spring 14 includes at least one stabilization coil 50 positioned within the through-hole 31 above the top retainer plate opening 55. In this configuration, the stabilization coil 50 vertically stabilizes the spring probe 34 in through-hole during assembly of the test socket.

In FIG. 9, the spring probe 34 is shown in an uncompressed, initial rest position. The outer diameter of the electrical spring probe 34 and inner diameter of the through-hole center portion 49 are set such that a coaxial structure of predetermined impedance is formed, wherein the spring probe 34 serves as a core conductor and the conductive substrate 27 serves as an outer conductor. The substrate top surface 46 and bottom surface 47, and the through-hole 31 can be insulated by anodizing or adding an insulated film such as polyimide or other insulated material to prevent shorting with the electrical spring probe 34, IC package or PCB.

Still referring to FIG. 9, the upper contact head 9 has a smaller diameter than that of the through-hole upper opening 30 to allow the contact head 9 to move within the through-hole upper opening 30 when the spring probe 34 is compressed. The diameter of the lower contact 43 is also smaller than the through-hole lower opening 33, allowing it to move vertically within the through-hole lower opening 33 when the spring 14 is compressed. The diameters of the upper insulated spacer 41a and the stabilization coil 50 are less than the inner diameter of the through-hole center portion 49 and are greater than the inner diameter of each of the upper opening 30 and lower opening 33, allowing the spring probe 34 to be retained within the substrate 27. The upper contact head 9 projects above the conductive substrate top surface 46, and the elongated lower contact 43 projects below the substrate bottom surface 47, enabling the lower contact 43 to extend beyond the substrate bottom surface 47 to make electrical contact with the PCB.

From the foregoing, it can be seen that the spring probe according to the present invention possesses numerous advantages. It can operate in a state-of-the-art controlled impedance coaxial configuration without sacrificing the probe spring operational life and compliance. Moreover, it can be easily manufactured and assembled with inexpensive components. In addition, the probe diameter is small enough to be used in the densities required by state of the art integrated circuit packages. It is suited to be used in contact assemblies at a high density so that a plurality of points concentrated in a small area may be accessed at the same time. It can be employed in various configurations for electrically accessing a variety of lead configurations on leading edge, area array, surface mount integrated circuit packages (BGA, LGA, MLF, WLP), either singulated or in multi-package strips or as wafer level packages. Also, the probe can have high current carrying capacity and minimum electrical resistance and inductance.

Additional advantages and modifications may readily occur to those skilled in the art. Therefore, the invention in its broader aspects is not limited to the specific details, representative devices, and illustrative examples shown and described. Accordingly, departures may be made from such details without departing from the spirit or scope of the general inventive concept.

What is claimed is:

1. An electrical spring probe for a connector assembly comprising:
a first elongated electrically conductive contact having a beam and having a head configured to contact an integrated circuit package;
a second elongated electrically conductive contact having a beam and a tip configured to contact an electrical conductor;
a compression spring having opposing first and second spring ends and a middle section intermediate the first and second spring ends, wherein the spring includes:
a first coiled section adjacent the first spring end and disposed about and in contact with the first contact beam; and
a stabilization section configured to stabilize the spring probe in a cavity in a test socket body during assembly of the test socket body; and
a second coiled section adjacent the second spring end and disposed about and in contact with the second contact beam; and
an insulated spacer disposed on the first conductive contact and having an annular surface configured to contact a wall of the cavity in the test socket body when the spring probe is positioned within the cavity.

2. The electrical spring probe of claim 1 wherein the insulated spacer is disposed on the first conductive contact intermediate the head and the first spring end.

3. The electrical spring probe of claim 1 further comprising a second insulated spacer disposed on the second conductive contact and having an annular surface configured to contact the cavity wall when the spring probe is positioned within the cavity.

4. The electrical spring probe of claim 1 wherein the first conductive contact beam includes an annular groove and the first coiled section includes one or more coils that fit in the annular groove.

5. The electrical spring probe of claim 1 wherein the first conductive contact includes a shoulder intermediate the head and the beam, wherein the shoulder restricts movement of the insulated spacer toward the head.

6. The electrical spring probe of claim 1 wherein the stabilization section includes at least one stabilization coil having a diameter larger than a diameter of the spring middle section.

7. The electrical spring probe of claim 6 wherein the stabilization coil is configured to closely fit within the cavity when the spring probe is positioned within the cavity.

8. The electrical spring probe of claim 1 wherein the first coiled section is fixed to the first conductive contact, and the insulated spacer is held in place on the first conductive contact by the first coiled section and the head.

9. The electrical spring probe of claim 1 wherein the first coiled section includes one or more coils having a coil diameter that is smaller than a coil diameter of an intermediate coiled section of the spring between the first coiled section and the second coiled section.

10. The electrical spring probe of claim 1 wherein the second coiled section includes one or more coils having a coil diameter that is smaller than a coil diameter of an intermediate coiled section of the spring between the first coiled section and the second coiled section.

11. An electrical spring probe for a connector assembly comprising:
an elongated electrically conductive contact having a beam and having a head for contacting an integrated circuit package;
a compression spring having opposing first and second spring ends, wherein the spring comprises:
a first coiled section adjacent the first spring end and disposed about and in contact with the contact beam; and
a second coiled section adjacent the second spring end; and
a stabilization section configured to stabilize the spring probe in a cavity in a test socket body during assembly of the test socket body; and
an insulated spacer fixed on the conductive contact and having an annular surface configured to contact a wall of the cavity when the spring probe is positioned within the cavity.

12. The electrical spring probe of claim 11 wherein the insulated spacer is fixed on the conductive contact intermediate the head and the first spring end.

13. The electrical spring probe of claim 11 wherein the conductive contact beam includes an annular groove and the first coiled section includes one or more coils that fit in the annular groove.

14. The electrical spring probe of claim 11 wherein the conductive contact includes a shoulder intermediate the head and the beam, and wherein the shoulder restricts movement of the insulated spacer toward the head.

15. The electrical spring probe of claim 1 wherein the first coiled section is fixed to the conductive contact, and the insulated spacer is held in place on the conductive contact by the first coiled section and the head.

16. The electrical spring probe of claim 11 wherein the first coiled section includes one or more coils having a coil diameter that is smaller than the coil diameter of an intermediate coiled section of the spring between the first coiled section and the second coiled section.

17. The electrical spring probe of claim 11 wherein the second coiled section includes one or more coils having a smaller coil diameter than the coil diameter of an intermediate coiled section of the spring between the first coiled section and the second coiled section.

18. The electrical spring probe of claim 11 wherein the stabilization section includes at least one stabilization coil having a diameter larger than a diameter of the first coiled section and larger than a diameter of the second coiled section

19. An electrical spring probe for a connector assembly comprising:
an elongated electrically conductive contact having a beam and having a head for contacting an integrated circuit package;
a compression spring having opposing first and second spring ends and a main spring axis, wherein the spring comprises:
a first coiled section adjacent the first spring end and fixed to the conductive contact;
a second coiled section adjacent the second spring end and fixed to a second conductive contact, and
a stabilization section intermediate the first and second coiled sections and configured to stabilize the spring probe vertically in a coaxial cavity of a test socket during assembly of the test socket.

20. The electrical spring probe of claim 19 wherein the stabilization section includes at least one stabilization coil disposed on an axis generally parallel to and offset from the main spring axis, wherein the stabilization coil outer diameter is smaller than a diameter of the coaxial cavity diameter and larger than outer diameters of the first coiled section and second coiled section.

21. The electrical spring probe of claim 19 wherein the stabilization section includes two vertically opposed stabilization coils, each of which has an outside diameter that is smaller than a diameter of the coaxial cavity diameter and larger than outer diameters of the first coiled section and second coiled section.
